(19) United States
(12) Patent Application Publication
(10) Pub. No.: US 2007/0057711 A1
(43) Pub. Date: Mar. 15, 2007

(54) Slewing rate adjustment circuit

(75) Inventor: Yasufumi Suzuki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/589,770

(22) Filed: Oct. 31, 2006

(30) Foreign Application Priority Data
Sep. 11, 2005 (JP) 2005-324851

(51) Int. Cl. H03K 5/12

(52) U.S. Cl. 327/170

(57) ABSTRACT

Disclosed is a slew rate adjustment circuit for adjusting the slew rate of an output buffer having an output transistor and a pre-transistor in a preceding stage of the output transistor which includes a resistance adjustment circuit and a resistance adjustment circuit. The resistance adjustment circuit and the resistance adjustment circuit adjust the resistances of a Pch output transistor and an Nch output transistor, in an output buffer, respectively. The slew rate adjustment circuit also includes a first resistance adjustment circuit and a second resistance adjustment circuit. The first resistance adjustment circuit and the second resistance adjustment circuit adjust the resistances of a Pch pre-transistor and an Nch pre-transistor, respectively. The slew rate adjustment circuit also includes a first fine resistance adjustment circuit and a second fine resistance adjustment circuit. The first fine resistance adjustment circuit receives the results of adjustment of the first resistance adjustment circuit to effect fine adjustment of the Pch pre-transistor and fine adjustment of the waveform gradient by a first external reference capacitance. The second fine second resistance adjustment circuit receives the results of adjustment of the second resistance adjustment circuit to effect fine adjustment of the Nch pre-transistor and fine adjustment of the waveform gradient by a second external reference capacitance. An output buffer is supplied with the results of adjustment by the first and second resistance adjustment circuits and those by the first and second fine resistance adjustment circuits.

### FIELD OF THE INVENTION

This invention relates to an output circuit of a semiconductor device. More particularly, this invention relates to a circuit for maintaining the output slew rate constant.

### BACKGROUND OF THE INVENTION

When an output buffer for outputting a signal, drives a transmission line, reflection occurs due to the difference between a characteristic impedance of the transmission line and a load impedance, thus producing distortion in the signal waveform. In particular, when, in case of high speed transmission of multiple inputs to a sole output buffer, as in DDR (Double Data Rate) or I/F, the waveform is made steep, there is produced the step difference in the waveform due to reflection in the transmission line. If conversely the slew rate of the waveform is diminished, there may be produced no sufficient amplitude swing, thus giving rise to malfunctions or timing inaccuracies. That is, adjustment of the slew rate of the output waveform of the output buffer is crucial.

FIG. 7 shows a typical example of a circuit configuration of an output buffer transmission line. FIG. 8 shows output waveforms of the results of simulation by SPICE (circuit simulator) of FIG. 7.

In FIG. 7, A0 denotes an ideal output buffer. For affording an ideal output buffer, FIG. 7 shows an equivalent circuit of the output buffer composed of a power supply A1 and a resistor A2. The power supply A1 is used for generating an output waveform of the output buffer A0 and is changed from 0V to 3.3V. The time during which the power supply changes in this manner, referred to below as gradient, is set to 0.1 ns, 0.5 ns and to 1.5 ns.

The resistor A2 has a resistance equivalent to the impedance of the output buffer A0. The resistance of the resistor is set to 50Ω matched to the transmission line.

A3 denotes a transmission line connected to an output end of the output buffer A0 and has an impedance of 50Ω and propagation delay of 0.5 ns.

A4 denotes a transmission line between branch points AA1 and AA2, having an impedance of 50Ω and propagation delay of 0.5 ns.

A5 denotes a transmission line between the branch point AA2 and a point of waveform observation AA3, having an impedance of 50Ω and propagation delay of 0.5 ns.

A6 denotes a dumping resistor for impedance matching at the branch point AA1 and has a resistance value of 25Ω.

A7 denotes a dumping resistor for impedance matching at the branch point AA2, and has a resistance value of 25Ω.

A8 denotes a transmission line between the dumping resistor A6 and an input semiconductor integrated circuit A10, and has an impedance of 50Ω and propagation delay of 0.2 ns.

A9 denotes a transmission line between the dumping resistor A7 and an input semiconductor integrated circuit A11, and has an impedance of 50Ω and propagation delay of 0.2 ns.

A13 denotes a terminal resistor connected to the point of waveform observation AA3, and has a resistance value of 50Ω.

To the point AA3 is also connected a semiconductor integrated circuit A12.

AA1 and AA2 denote branch points of the transmission lime.

A10, A11 and A12 each denote a semiconductor integrated circuit receiving an output signal of A0 and having an input capacitance Cin=2 pF.

FIG. 8 shows waveforms of the results of simulation by SPICE at the point of waveform observation AA3 of FIG. 7.

In FIG. 8, B1, B2 and B3 stand for waveforms with the gradients of A1 equal to 0.1 ns, 0.5 ns and 1.5 ns, respectively.

As may be seen from FIG. 8, the waveform B1 suffers from a step difference, ascribable to reflection, in the vicinity of 1.6V, thus possibly causing malfunctions of the semiconductor integrated circuit A12. The waveform B3 has a waveform of a triangular waveform such that there is generated no amplitude of the voltage in order for the semiconductor integrated circuit A12 to be in operation. Conversely, with the waveform B2, the semiconductor integrated circuit A12 may be in operation as normally.

The gradient of the output waveform of 0.5 ns yields the normal operation. Conversely, the gradient of 0.1 ns or 1.5 ns gives rise to malfunctions. Except if the gradient of the output waveform is corrected, malfunctions will necessarily be produced.

So far, the customary practice in adjusting the slew rate has been to make the resistance value of the output buffer constant and to make the resistance value of a buffer driving the output buffer constant. The buffer driving the output buffer is termed a pre-buffer. The buffer is termed a pre-buffer (pre-buffer having a push-pull configuration). That is, the on-resistance values of Pch and Nch output transistors of the output buffer of the push-pull configuration for driving the transmission line, and those of Pch and Nch pre-transistors of the pre-buffer of the push-pull configuration for driving the output transistors, are maintained at constant values.

FIG. 9 shows an example of the configuration of a typical conventional slew rate adjustment circuit Z2. An adjustment controller circuit 1 controls the operation and the halting of the operation of resistance adjustment circuits 2 to 5. Meanwhile, in FIG. 9, for example, the transistors are abbreviated to TR, as in a Pch output TR resistance adjustment circuit for a Pch output transistor resistance adjustment circuit.

The Pch output transistor resistance adjustment circuit 2 is used for adjusting the resistance value of a Pch output transistor of the output buffer.

The Nch output transistor resistance adjustment circuit 3 is used for adjusting the resistance value of an Nch output transistor of the output buffer.

The Pch pre-transistor resistance adjustment circuit 4 is used for adjusting the resistance value of a Pch pre-transistor of the pre-buffer.

The Nch pre-transistor resistance adjustment circuit 5 is used for adjusting the resistance value of an Nch pre-transistor of the pre-buffer.

The I/F buffer 6 is connected to the transmission line 7. The resistance values of the output buffer and the pre-buffer are adjusted to the same resistance values as those of the resistance adjustment circuits 2 to 5. That is, the resistance values of the Pch and Nch transistors of the output buffer, not shown, in the I/F buffer 6, are set so as to be equal to the resistance values of the Pch output TR resistance adjustment circuit 2 and the Nch output TR resistance adjustment circuit 3, respectively, based on a Pch output TR resistance adjustment output S9 from the Pch output TR resistance adjustment circuit 2 and on an Nch output TR resistance adjustment output S10 from the Nch output TR resistance adjustment circuit 3. On the other hand, the resistance values of the Pch and Nch transistors of the pre-buffer, not shown, of the I/F buffer 6, are set so as to be equal to those of the Pch pre-TR resistance adjustment circuit 4 and the Nch pre-TR resistance adjustment circuit 5, based on a Pch pre-TR resistance adjustment output S11 from the Pch pre-TR resistance adjustment circuit 4 and on an Nch pre-TR resistance adjustment output S12 from the Nch pre-TR resistance adjustment circuit 5.

A resistor 10 generates a reference voltage signal REF used for resistance adjustment by resistor-division.

The resistor 11 is a resistor termed a ‘reference resistor’ for adjusting the on-resistance of a transistor of the Pch output transistor resistance adjustment circuit 2 for realization of resistance coincidence.

The resistor 12 is used as a reference resistor for the Nch output transistor resistance adjustment circuit 3.

The resistor 13 is used as a reference resistor for the Pch pre-transistor resistance adjustment circuit 4.

The resistor 14 is used as a reference resistor for the Nch pre-transistor resistance adjustment circuit 5.

The adjustment controller circuit 1 and the resistance adjustment circuits 2 to 5 are in operation in synchronization with a sole clock signal CLK.

The reference voltage signal REF is received as an input by the resistance adjustment circuits 2 to 5.

FIG. 11 shows an example of the configuration of the Pch pre-transistor resistance adjustment circuit 4 shown in FIG. 9. Referring to FIG. 11, a counter 121 is a two-bit counter to an enable terminal EN of which is supplied an adjustment start input S5 as an input. When the adjustment start input S5 is at HIGH level, the counter counts up in synchronization with the rising of the clock signal CLK to transmit two-bit count values S1 and S2. When the adjustment start input S5 is at LOW level, the counter is disabled, such that it does not count up even though the clock signal CLK rises.

A selector 122 causes the states of output terminals O1 to O4 to be changed by input signals at count outputs S1 and S2 of the counter 121. The states of the output terminals O1 to O4 are as shown in Table 1, only by way of illustration. In this table, L and H denote LOW and HIGH levels, respectively.

TABLE 1

| S1 | S2 | O1 | O2 | O3 | O4 |
|---|---|---|---|---|---|
| L | L | L | H | H | H |
| L | H | L | L | H | H |
| H | L | L | L | L | H |
| H | H | L | L | L | L |

A set of Pch pre-transistors 123 is here made up of four Pch transistors 123-1 to 123-4. The gate widths and gate lengths of the Pch transistors 123-1 to 123-4, as well as the number of the transistors, are designed so as to be coincident with those of the transistors of the I/F buffer 6 (see FIG. 9). First to fourth Pch transistors 123-1 to 123-4 are turned on for four combinations of the count outputs S1 and S2 of from (LOW, LOW) to (HIGH, HIGH).

The gates of the Pch transistors 123-1 to 123-4 are coupled to corresponding signals O1 to O4. The sources of the Pch transistors are connected in common to the power supply VDD which is the same as that for the I/F buffer 6. The drains of the Pch transistors are coupled by wired connection to a signal SS3.

A comparator 124 is a two-input voltage comparator and compares the input reference voltage signal REF with the voltage on SS3. If REF≧SS3, the comparator sets an adjustment end output S6 to the LOW level. If REF<SS3, the comparator sets the adjustment end output S6 to the HIGH level. The two-bit count outputs S1 and S2 of the counter 121, with the adjustment end output S6 at HIGH level, are supplied to the I/F buffer 6, as an adjustment result output S11 of the Pch pre-transistor resistance adjustment circuit 4, such as to adjust the resistance of the pre-buffer of the I/F buffer 6.

The resistance adjustment circuits 2, 3 and 5 in FIG. 9 are configured similarly to the Pch pre-transistor resistance adjustment circuit 4 of FIG. 11. Simply the set of Pch pre-transistors 123 is replaced by the circuit like the Pch and Nch output transistors and Nch pre-transistors in the inside of the I/F buffer 6 and, insofar as the circuit for adjusting the Nch transistors is concerned, the logic of the outputs O1 to O4 of the selector 122 is inverted. In similar manner, the circuitry of the resistance adjustment circuits 2, 3 and 5 is of the same configuration as that of the resistance adjustment circuit 4. That is, by matching the resistances of the resistors 11 to 14 and the on-resistances of the transistors, formed within the chip, it becomes possible to suppress variations in the on-resistances of the transistors, otherwise caused by manufacture tolerance or by differences in the conditions of use, such as voltages, thereby achieving impedance matching with respect to the transmission line and slew rate adjustment.

The sequence of operations for adjusting transistor resistances in the I/F buffer 6 of FIG. 9 will now be described.

FIG. 10 is a flowchart for illustrating the processing for adjusting the resistance values in the I/F buffer 6 of FIG. 9. The sequence of operations for adjustment will now be described with reference to FIGS. 9 and 10.

In a step F1, a Pch output transistor, not shown, of the I/F buffer 6 is adjusted. The Pch output transistor resistance adjustment circuit 2 is activated to adjust the resistance value of the Pch output transistor of the I/F buffer 6.

In case the resistance value of the Pch output transistor, not shown, of the I/F buffer 6, is not coincident with the resistance value of the resistor (reference resistor) 11, that is, in case of NO branching of step F2, processing reverts to the step F1 to effect re-adjustment.

In case the resistance value of the Pch output transistor, not shown, of the I/F buffer 6, is coincident with the resistance value of the resistor 11, that is, in case of YES branching of step F2, processing transfers to a step F3. The results of adjustment are output to the I/F buffer 6 to adjust the resistance value of the Pch output transistor.

In a step F4, the Nch transistor, not shown, of the I/F buffer 6 is adjusted. The Nch output transistor resistance adjustment circuit 3 is activated to adjust the resistance value of the Nch output transistor of the I/F buffer 6.

In case the resistance value of the Nch output transistor, not shown, of the I/F buffer 6, is not coincident with the resistance value of the resistor 12, that is, in case of NO branching of step F5, processing reverts to the step F4 to effect re-adjustment.

In case the resistance value of the Nch output transistor, not shown, of the I/F buffer 6, is coincident with the resistance value of the resistor 12, that is, in case of YES branching of step F5, processing transfers to a step F6. The results of adjustment are output to the I/F buffer 6 to adjust the resistance value of the Pch output transistor.

In the next step F7, the Pch pre-transistor, not shown, of the I/F buffer 6 is adjusted. The Pch pre-transistor resistance adjustment circuit 4 is activated to adjust the resistance value of the Pch pre-transistor of the I/F buffer 6.

In case the resistance value of the Pch pre-transistor, not shown, of the I/F buffer 6, is not coincident with the resistance value of the resistor 13 (NO branching of step F8), processing reverts to the step F7 to effect re-adjustment.

In case the resistance value of the Pch pre-transistor, not shown, of the I/F buffer 6, is coincident with the resistance value of the resistor 13 (YES branching of step F8), processing transfers to a step F9. The results of adjustment are output to the I/F buffer 6 to adjust the resistance value of the Pch pre-transistor, not shown.

In a step F13, the Nch pre-transistor, not shown, of the I/F buffer 6 is adjusted. The Nch pre-transistor resistance adjustment circuit 5 is activated to adjust the resistance value of the Nch pre-transistor, not shown, of the I/F buffer 6.

In case the resistance value of the Nch pre-transistor, not shown, of the I/F buffer 6, is not coincident with the resistance value of the resistor 14 (NO branching of step F14), processing reverts to the step F13 to effect re-adjustment.

In case the resistance value of the Nch pre-transistor, not shown, of the I/F buffer 6, is coincident with the resistance value of the resistor 14 (YES branching of step F14), processing transfers to a step F15. The results of adjustment are output to the I/F buffer 6 to adjust the resistance value of the Nch pre-transistor, not shown.

With the above steps, adjustment of resistance values of the transistors, not shown, of the I/F buffer 6, comes to a close. Thus, at the next step S16, the operation of the I/F buffer 6 is commenced.

FIG. 12 is a timing chart for illustrating the processing for adjustment of the Pch Pre-transistor in the step F7 in the flowchart of FIG. 10.

When the clock signal CLK rises to HIGH level, at a timing T1, an output SS1 of the counter 121 is changed to HIGH level. This causes the operation of the selector 122 so that the output O2 is changed to LOW level. The Pch transistor 123-2 in the set of Pch pre-transistors 123 is turned on so that the voltage level of the signal SS3 rises.

When the clock signal CLK rises to HIGH level, at a timing T2, the output SS1 of the counter 121 is changed to the LOW level, at the same time as an output SS2 is changed to HIGH level.

When the output O2 of the selector 122 becomes LOW level, the Pch transistor 123-3 of the set of Pch pre-transistors 123 is turned on, so that the voltage level of the signal SS3 is raised further. Since the voltage of the signal SS3 becomes higher at this time point than the voltage of the reference voltage signal REF, the adjustment end output S6 is changed to HIGH level.

On detecting that the adjustment end output S6 has become HIGH level, the adjustment controller Z2 causes the adjustment start input S5 to go low in level, at a timing T4, to halt the operation of the counter 121 as from this time.

The outputs SS1 and SS2 of the counter 121 at this time are output as adjustment result output S11 to the I/F buffer 6, to set the resistance value of the Pch pre-transistor, not shown, of the I/F buffer 6.

The slew rate of the output buffer is determined from the time of transition of the gate potential of the output transistor.

The time of transition of the gate potential of the output transistor, in turn, is determined by the resistance value of the driving transistor and the capacitance value of the output transistor.

### SUMMARY OF THE DISCLOSURE

In the above-described conventional slew rate adjustment circuit, adjustment is made by the resistance adjustment circuits so that the resistance values will be constant.

However, since the gate capacitance of an output transistor is fluctuated, depending on the fabrication processes and on the use-conditions, the slew rate is fluctuated. The gate capacitances of a transistor depend on the thicknesses of an oxide film and a gate area. Since the thickness of the oxide film and the gate lengths are fluctuated by approximately 10% and approximately 5%, respectively, the gate capacitance and the capacitance value are each fluctuated by 15%.

Even though the resistance values of the pre-buffer transistors are constant, the gate voltage transition time of the output transistor is fluctuated, in response to the capacitance fluctuations of 15%. Thus, the resistance transition of the output transistor is fluctuated, such that the slew rate is also fluctuated.

An example of fluctuations of the gate capacitance CB12, the time of transition of the gate voltage ΔVG, and the resistance values R of the output transistors, are shown below.
CB12 Tₒₓ=6.7 nm (67A)˜8.1 nm (81A)±9% L=0.34 μm to 0.38 μm+6% TOTAL 15%

Time of transition of the gate voltage
ΔVG=exp(t/tr)−exp(t/1.15rc)
where t denotes time, tr denotes rise time, rc denotes time constant and exp denotes an exponential function.
.Output transistor resistance R=β{(VG−VT)VD −(½)VD²}/VD
where β denotes the transconductance of the transistor (β=(με/tₒₓ) (W/L); μ denotes a mobility of carrier, ε denotes dielectric constant of a gate insulating film, tₒₓ denotes a film thickness of the gate insulating film, W denotes a channel width and L denotes a channel length), VG denotes a gate voltage (gate-to-source voltage), VT denotes a threshold value and VD denotes a drain voltage (drain-to-source voltage).

FIG. 13 shows a basic circuit of the output buffer. In FIG. 13, 31 denotes pre-buffers (pre-drivers), 32 denotes output transistors (push-pull output transistors). 33 denotes the capacitance driven by the output buffer, S30 denotes an input signal, S35 and S36 denote outputs of pre-buffers driving the Pch and Nch output transistors, and S34 denotes an output of the output buffer.

FIG. 14 shows waveforms, obtained by SPECE simulation, just before and just after decrease by 15% of the gate capacitance of the output transistors 32 of FIG. 13.

In FIG. 14,

WS30 denotes a waveform of an input signal S30;

WS34 denotes a waveform of S34 just before decrease by 15% of the gate capacitance;

WS35 denotes a waveform of S35 just before decrease by 15% of the gate capacitance;

WS36 denotes a waveform of S36 just after decrease by 15% of the gate capacitance;

BS34 denotes a waveform of S34 just after decrease by 15% of the gate capacitance;

BS35 denotes a waveform of S35 just after decrease by 15% of the gate capacitance; and

BS36 denotes a waveform of S36 just after decrease by 15% of the gate capacitance.

It may be seen that, with decrease by 15% of the gate capacitance of the output transistor 32, the gradient of outputs S35 and S36 of the pre-buffers 31 is changed, with the gradient of the output S34 of the output buffer being further changed significantly. That is, the slew rate of the output buffer is changed significantly by fluctuations in the gate capacitance of the output transistor 32.

FIG. 15 shows a waveform on a transmission line of a conventional slew rate adjustment circuit. In FIG. 15, OW denotes a waveform with which the input to the semiconductor integrated circuit may be effected normally under certain conditions of fabrication and use.

A waveform OB0 is obtained on matching resistance values by conventional slew rate adjustment under conditions of fabrication and use differing from those for OW.

The waveform OW suffers from step difference at OBX in the vicinity of 1.5V and hence represents a waveform with which the input to the IC cannot be effected as normally.

Thus, the conventional slew rate adjustment circuit, described above, leaves much to be desired in that the slew rate of the output buffer is significantly changed by variations in the gate capacitance of the output transistors 32.

To solve the above problem, the invention disclosed in the present application is configured substantially as follows:

A slew rate adjustment circuit according to the present invention is a circuit for adjusting the slew rate of an output buffer which includes a pre-buffer in a preceding stage of an output transistor. The slew rate adjustment circuit includes a controlling circuit for variably controlling the resistance value of a transistor of the pre-buffer depending on the gate capacitance of the output transistor. The resistance value of the transistor of the pre-buffer is adjusted for canceling out variations in the gate capacitance of the output transistor so that the slew rate of the output transistor is adjusted to a preset value.

The slew rate adjustment circuit according to the present invention may include a first resistance adjustment circuit for adjusting the resistance of an output transistor of the first conductivity type of the output buffer, and a second resistance adjustment circuit for adjusting the resistance of an output transistor of the second conductivity type of the output buffer. The slew rate adjustment circuit may further include a third resistance adjustment circuit for adjusting the resistance of a pre-transistor of the first conductivity type of the pre-buffer, and a fourth resistance adjustment circuit for adjusting the resistance of a pre-transistor of the second conductivity type of the pre-buffer. The slew rate adjustment circuit may further include a first fine resistance adjustment circuit, receiving the result of adjustment by the third resistance adjustment circuit and performing fine adjustment of the resistance value of the pre-transistor of the first conductivity type of the pre-buffer for performing fine adjustment of the waveform gradient based on a reference capacitance. The slew rate adjustment circuit may further include a second fine resistance adjustment circuit, receiving the result of adjustment by the fourth resistance adjustment circuit and performing fine adjustment of the resistance value of the pre-transistor of the second conductivity type of the pre-buffer for performing fine adjustment of the waveform gradient based on another reference capacitance. The results of adjustment by the first resistance adjustment circuit and the second resistance adjustment and the results of adjustment by the first fine resistance adjustment circuit and the second fine resistance adjustment circuit are supplied to the output buffer as inputs to control the slew rate of the output buffer.

In the slew rate adjustment circuit, according to the present invention, the first fine resistance adjustment circuit may include a first transistor of a second conductivity type, the gate of which receives a clock signal, and a first reference pre-transistor buffer including a plurality of transistors of the first conductivity type. The transistors are connected in parallel one with another between the first transistor of the second conductivity type and a power supply and are on/off controlled by control signals applied to the respective gates of the transistors. The first fine resistance adjustment circuit may further include a second transistor of the second conductivity type, the gate of which receives the clock signal, and a second reference pre-transistor buffer including a plurality of transistors of the first conductivity type. The transistors are connected in parallel one with another between the second transistor of the second conductivity type and a power supply and are on/off controlled by control signals applied to the respective gates of the transistors. The first fine resistance adjustment circuit may further include an adjustment pre-transistor buffer including a plurality of transistors of the first conductivity type. The transistors are connected in parallel one with another between the second transistor and a power supply and are on/off controlled by control signals applied to the respective gates of the transistors. The first fine resistance adjustment circuit may further include an external capacitor receiving an output of the first reference pre-transistor buffer and constituting the reference capacitance, and an output transistor, the gate of which receives an output of the adjustment pre-transistor buffer. The first fine resistance adjustment circuit may further include a waveform comparator circuit comparing the waveform of an output signal of the first reference pre-transistor buffer and the waveform of an output signal of the adjustment pre-transistor buffer to each other and outputting an adjustment end signal based on the result of comparison. The first fine resistance adjustment circuit may further include a gate capacitance correction circuit receiving the adjustment end signal output from the waveform comparator circuit and outputting a control signal which is to be supplied to the gate of the adjustment pre-transistor buffer.

In the slew rate adjustment circuit, according to the present invention, the second fine resistance adjustment circuit may include a first transistor of a first conductivity type, the gate of which receives a clock signal, and a first reference pre-transistor buffer including a plurality of transistors of the second conductivity type. The transistors are connected in parallel one with another between the first transistor of the first conductivity type and a power supply and are on/off controlled by control signals applied to the respective gates of the transistors. The second fine resistance adjustment circuit may further include a second transistor of the first conductivity type, the gate of which receives the clock signal, and a second reference pre-transistor buffer including a plurality of transistors of the second conductivity type. The transistors are connected in parallel one with another between the second transistor of the first conductivity type and a a power supply and are on/off controlled by control signals applied to the respective gates of the transistors. The second fine resistance adjustment circuit may further include an adjustment pre-transistor buffer including a plurality of transistors of the second conductivity type. The transistors are connected in parallel one with another between the second transistor and a power supply and are on/off controlled by control signals applied to the respective gates of the transistors. The second fine resistance adjustment circuit may further include an external capacitor receiving an output of the first reference pre-transistor buffer at an end thereof and constituting the reference capacitance, and an output transistor, the gate of which receives an output signal of the adjustment pre-transistor buffer. The second fine resistance adjustment circuit may further include a waveform comparator circuit comparing the waveforms of an output signal of the first reference pre-transistor buffer and an output signal of the adjustment pre-transistor buffer to each other and outputting an adjustment end signal based on the result of comparison. The second fine resistance adjustment circuit may further include a gate capacitance correction circuit receiving the adjustment end signal output from the waveform comparator circuit as an input and outputting a control signal which is to be supplied to the gate of the adjustment pre-transistor buffer.

In the slew rate adjustment circuit, according to the present invention, the first fine resistance adjustment circuit may include a circuit receiving the result of adjustment by the third resistance adjustment circuit to generate a signal to be supplied to the gates of a plurality of transistors of the second conductivity type of the first and second reference pre-transistor buffers in accordance with an output of the result of adjustment by the third resistance adjustment circuit.

In the slew rate adjustment circuit, according the present invention, the second fine resistance adjustment circuit may include a circuit receiving the result of adjustment by the fourth resistance adjustment circuit as an input to generate a signal to be supplied to the gates of a plurality of transistors of the second conductivity type of the first and second reference pre-transistor buffers in accordance with an output of the result of adjustment by the third resistance adjustment circuit.

According to the present invention, the first and third resistance adjustment circuits may each include a counter for counting an input clock signal, a plurality of transistors of the first conductivity type, receiving an output of the counter at the respective gates thereof and being connected in parallel one with another between a power supply and a reference resistor, and a comparator for comparing the voltage at a connection node of the plural transistors of the first conductivity type and the reference resistor and an input reference voltage to output an adjustment end signal based on the result of comparison. An output of the counter at the end of adjustment is used as the result of adjustment.

According to the present invention, the second and fourth resistance adjustment circuits may each include a counter for counting an input clock signal, a plurality of transistors of the second conductivity type, receiving an output of the counter at the respective gates thereof and being connected in parallel one with another between a power supply and a reference resistor, and a comparator for comparing the voltage at a connection node of the plural transistors of the second conductivity type and the reference resistor and an input reference voltage to output an adjustment end signal based on the result of comparison. An output of the counter at the end of adjustment is used as the result of adjustment.

According to the present invention, resistance adjustment by the first and second resistance adjustment circuits is carried out sequentially and the results of adjustment are supplied to the output buffer, whilst resistance adjustment by the third and fourth resistance adjustment circuits is carried out sequentially. Adjustment of the waveform gradient by the reference capacitance in the first fine resistance adjustment circuit and that in the second fine resistance adjustment circuit are carried out sequentially. The results of adjustment by the first and second fine resistance adjustment circuits are supplied to the output buffer.

The meritorious effects of the present invention are summarized as follows.

According to the present invention, the desired slew rate may be set as the fluctuations in the gate capacitance of the output transistor are canceled out by adjusting the resistance of a pre-driver. With the present invention, it is possible to prohibit the slew rate of the output buffer from being significantly changed due to variations in the gate capacitance.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of a slew rate adjustment circuit according to an embodiment of the present invention.

FIG. 2 is a flowchart showing the sequence of operations in adjusting the slew rate embodying the present invention.

FIG. 3 is a circuit diagram showing the configuration of a fine Pch pre-transistor resistance adjustment circuit according to an embodiment of the present invention.

FIG. 4 is a timing diagram showing the signal waveform according to an embodiment of the present invention.

FIG. 5 is a schematic diagram showing the circuit configuration of a transmission line according to an embodiment of the present invention.

FIG. 6 is a graph showing signal waveforms indicating the results of simulation by SPICE of FIG. 5.

FIG. 7 is a schematic diagram showing the circuit configuration of an output buffer transmission line.

FIG. 8 is a graph showing signal waveforms indicating the results of simulation by SPICE of FIG. 7.

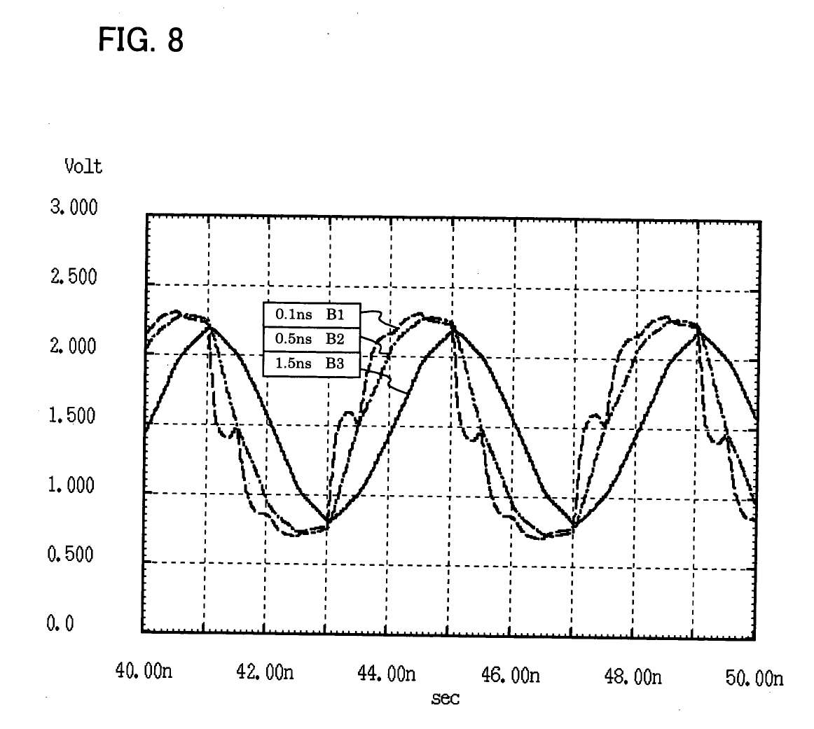

FIG. 9 shows the configuration of a conventional slew rate adjustment circuit.

FIG. 10 is a flowchart showing the sequence of operations for conventional slew rate adjustment.

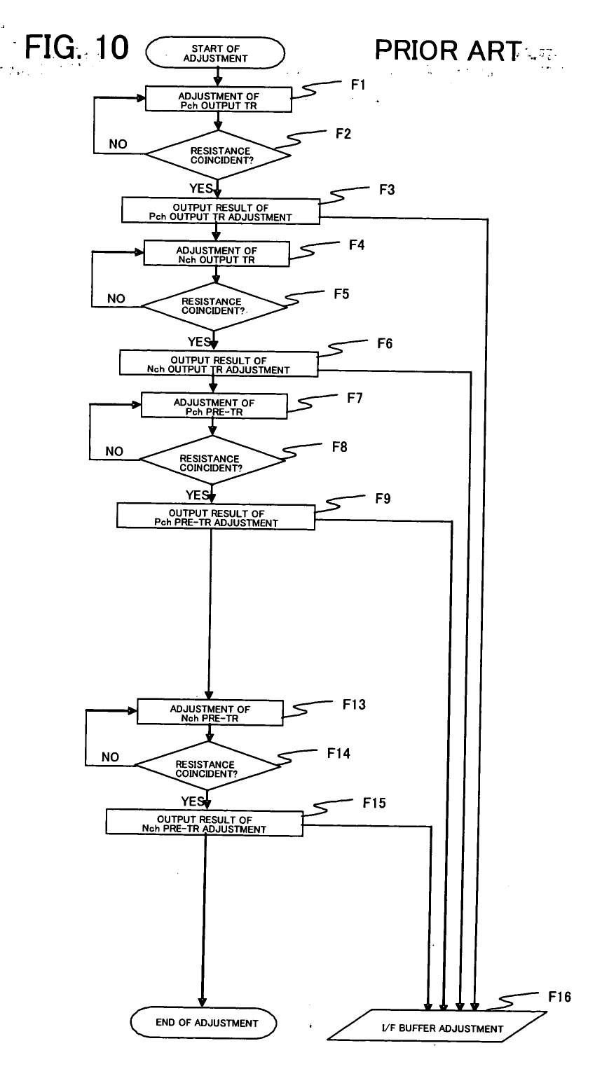

FIG. 11 is a circuit diagram showing an illustrative configuration of a conventional Pch pre-transistor resistance adjustment circuit.

FIG. 12 is a timing chart for conventional Pch pre-transistor resistance adjustment.

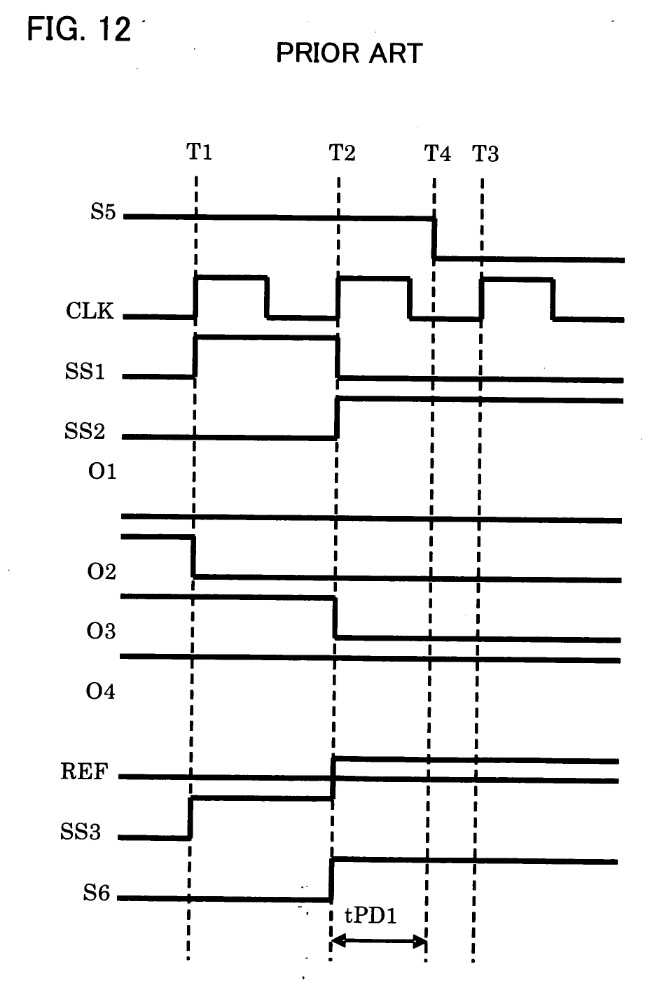

FIG. 13 is a circuit diagram showing a basic circuit configuration of an output buffer.

FIG. 14 is a graph showing the SPICE waveform of FIG. 13.

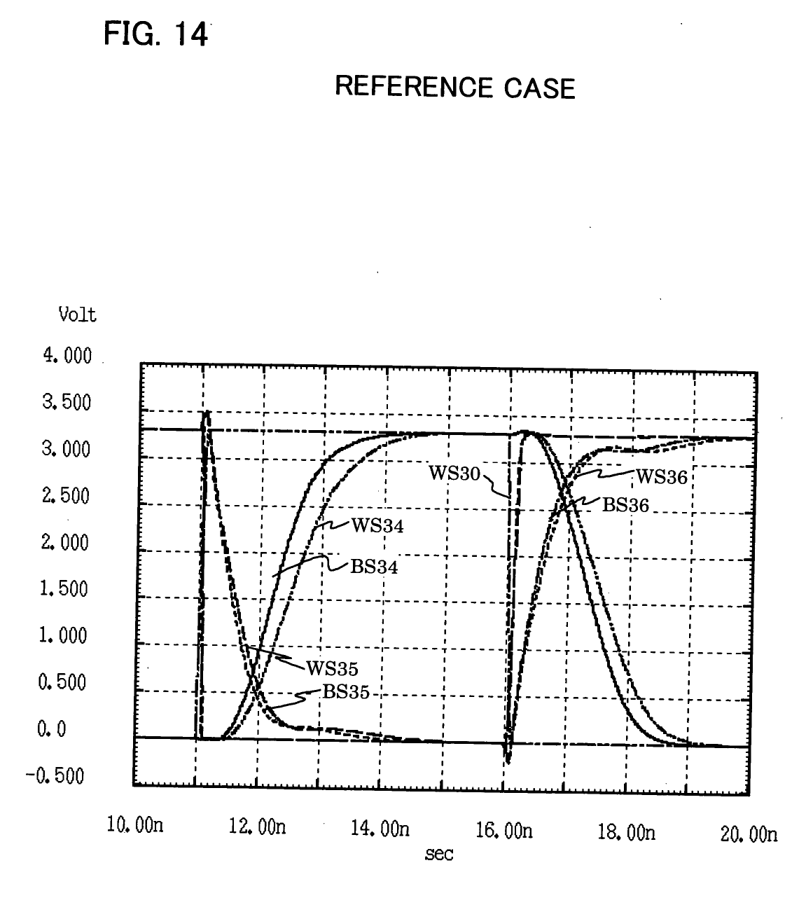

FIG. 15 is a graph showing the waveform of a conventional transmission line.

### PREFERRED EMBODIMENTS OF THE INVENTION

Reference is made to the accompanying drawings hereinbelow for describing the present invention in more detail.

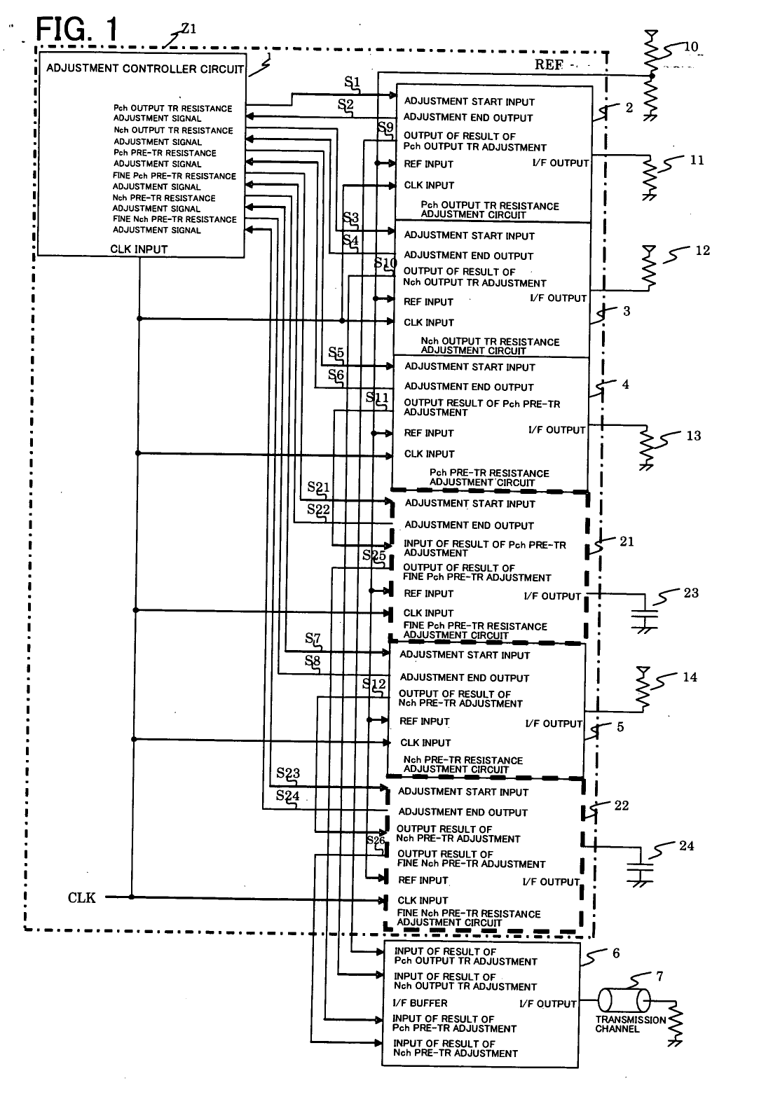

According to the present invention, the slew rate adjustment circuit, that is, the circuit for adjusting the slew rate of an output buffer, compares the external capacitors (23 and 24 of FIG. 1), provided as reference capacitances, through comparison of waveforms, and variably adjusts the resistance value of the pre-transistors in a pre-buffer to reduce the variations in the slew rate ascribable to variations in the gate capacitance.

An external capacitor is appreciably higher in the capacitance value accuracy than the gate capacitance. In the case of ACCU-P series of the commercially available capacitor, manufactured by KYO-CERA, C≦5.6 pF 0.05 pF±1%.

A slew rate adjustment circuit Z1, for adjusting the slew rate of an output buffer, includes a resistance adjustment circuit (2) for adjusting the resistance of a Pch output transistor, a resistance adjustment circuit (3) for adjusting the resistance of an Nch output transistor of the output buffer, a resistance adjustment circuit (4) for adjusting the resistance of a Pch pre-transistor, and a resistance adjustment circuit (5) for adjusting the resistance of an Nch pre-transistor in the output buffer. The slew rate adjustment circuit also includes a fine resistance adjustment circuit (21) that receives the result of adjustment of the resistance adjustment circuit (4) and effects fine adjustment of the Pch pre-transistor and fine adjustment of the waveform gradient by an external reference capacitance (23), and another fine resistance adjustment circuit (22) that receives the result of adjustment of the resistance adjustment circuit (5) and effects fine adjustment of the Nch pre-transistor and fine adjustment of the waveform gradient by another external reference capacitance (24). An output buffer (6) is supplied with the results of adjustment by the resistance adjustment circuits (2, 3) for adjusting the resistances of the output transistors, and with the results of adjustment by the fine resistance adjustment circuits (21, 22) of the resistance of the pre-transistor (waveform gradient). The slew rate is adjusted by adjusting the resistance value of the pre-transistor such as to cancel out the variations in the gate capacitance of the output transistor.

According to the present invention, a transient waveform of an RC series circuit of high accuracy may be obtained by a driving transistor adjusted in its resistance and by a capacitance of high accuracy.

The slew rate is adjusted by a circuit adapted for comparing the waveform of a pre-buffer, driving the gate of the transistor, with the above transient waveform, as a reference waveform, and for matching the resistance value of the driving transistor of the pre-buffer to the reference resistance. A preferred embodiment of the present invention will now be described in detail.

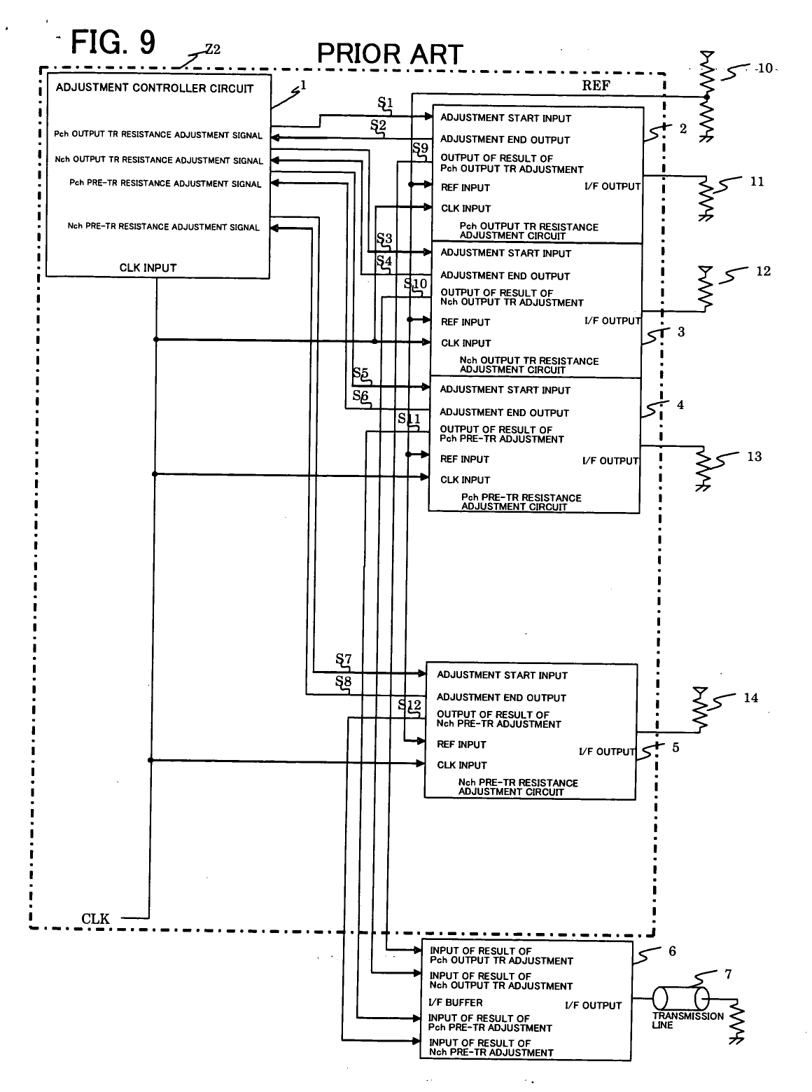

FIG. 1 is a circuit diagram showing the configuration of a slew rate adjustment circuit Z1 of the present invention. In FIG. 1, the same components as those of the conventional slew rate adjustment circuit of FIG. 9 are denoted by the same reference numerals. That is, the reference numerals 2 to 7 and 10 to 14 denote the same components as those denoted by corresponding reference numerals of FIG. 9. Moreover, in FIG. 1, signals S1 to S10, namely the signal S1 (adjustment start input), signal S2 (adjustment end output), signal S3 (adjustment start input), signal S4 (adjustment end output), signal S5 (adjustment start input), signal S6 (adjustment end output), signal S7 (adjustment start input), signal S8 (adjustment end output), signal S9 (output for the result of Pch output TR adjustment) and the signal S10 (output for the result of Nch output TR adjustment) are the same as the inputs or outputs of corresponding reference numerals of FIG. 9. In the following description, with reference to FIG. 1, the same components as those of FIG. 9 are not explained and mainly the points of difference will be explained. In the following description with reference to FIGS. 1, 2 or 3, for example, the transistor is abbreviated to TR, such as in Pch output TR resistance adjustment circuit.

Referring to FIG. 1, fine Pch pre-transistor resistance adjustment signals S21 and S22 and fine Nch pre-transistor resistance adjustment signals S23 and S24, shown in the adjustment controller circuit 1, are added to the configuration shown in FIG. 9.

There are further added a fine Pch pre-transistor resistance adjustment circuit 21, a fine Nch pre-transistor resistance adjustment circuit 22, a capacitor 23, as reference capacitance for the fine Pch pre-transistor resistance adjustment circuit 21, and a capacitor 24, as reference capacitance for the fine Nch pre-transistor resistance adjustment circuit 22.

S21 denotes a signal supplied to an adjustment start input of the fine Pch pre-transistor resistance adjustment circuit 21.

S22 denotes a signal supplied from an adjustment end output of the fine Pch pre-transistor resistance adjustment circuit 21.

S23 denotes a signal supplied to an adjustment start input of the fine Nch pre-transistor resistance adjustment circuit 22.

S24 denotes a signal supplied from an adjustment end output of the fine Nch pre-transistor resistance adjustment circuit 22.

S25 denotes a signal supplied to the input for the result of fine Pch pre-transistor adjustment of the I/F buffer 6 from the output for the result for fine Pch pre-transistor adjustment of the fine Pch pre-transistor resistance adjustment circuit 21.

S26 denotes a signal supplied to the input for the result of fine Nch pre-transistor adjustment of the I/F buffer 6 from the output for the result of fine Nch pre-transistor adjustment of the fine Nch pre-transistor resistance adjustment circuit 22.

In the circuit of FIG. 9, S11 (output for the result of adjustment of the Pch pre-TR) is connected to the input for the result of adjustment of the Pch pre-TR of the I/F buffer 6. In the present embodiment, S11 (output for the result of Pch pre-TR adjustment) is connected to the input for the result of adjustment of the Pch pre-transistor of the fine Pch pre-transistor resistance adjustment circuit 21.

In the circuit of FIG. 9, S12 (output for the result of Nch pre-TR adjustment) is connected to the input for the result of Nch pre-transistor adjustment of the I/F buffer 6. In the present embodiment, S12 (output for the result of Nch pre-TR adjustment) is connected to the input for the result of Nch pre-transistor adjustment of the fine Nch pre-transistor resistance adjustment circuit 22.

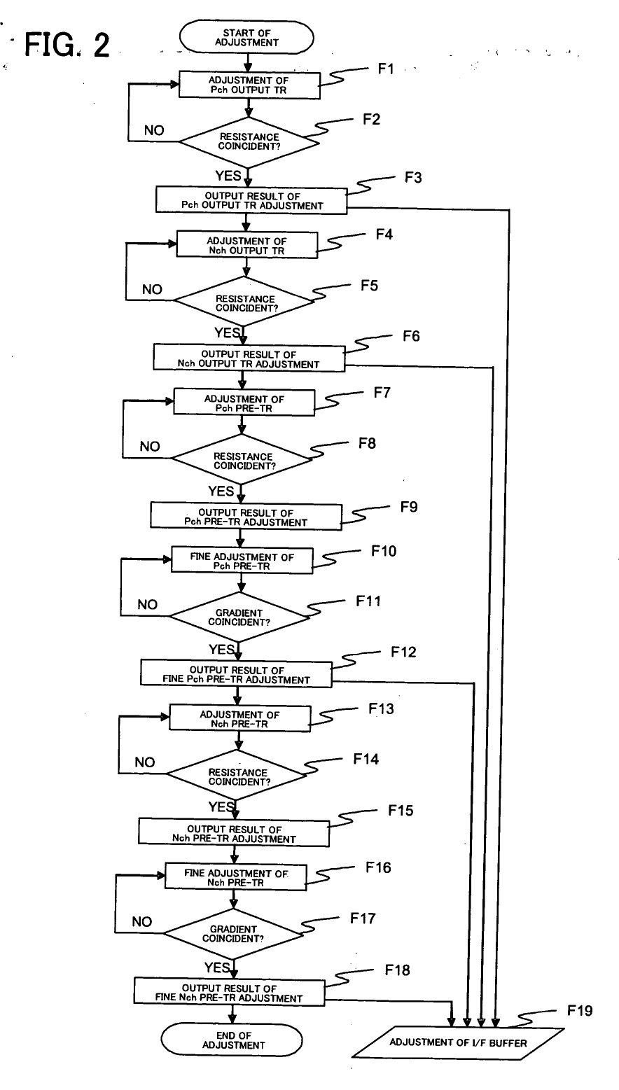

FIG. 2 is a flowchart for illustrating the processing for adjusting the resistance values of the transistors of the I/F buffer (output buffer) 6 in the present embodiment. Referring to FIGS. 1 and 2, the sequence of operations for adjusting the resistance values of the transistors of the I/F buffer 6 will be described.

In a step F1, the Pch output transistor resistance adjustment circuit 2 for adjusting the resistance value of the Pch output transistor, not shown, of the I/F buffer (output buffer) 6, is activated to adjust the resistance value of the Pch output transistor of the I/F buffer 6.

In case the resistance value of the Pch output transistor, not shown, of the I/F buffer 6, is not coincident with the resistance value of the resistor 11 (NO branching of the step F2), processing reverts to the step F1 to make re-adjustment.

In case the resistance value of the Pch output transistor, not shown, of the I/F buffer 6 is coincident with the resistance value of the resistor 11 (YES branching of the step F2), processing transfers to a step F3 to output the result of adjustment to the I/F buffer 6 to adjust the resistance value of the Pch output transistor, not shown.

In a step F4, the Nch output transistor, not shown, of the I/F buffer 6 is adjusted. The Nch output transistor resistance adjustment circuit 3 is activated to adjust the resistance value of the Nch output transistor, not shown, of the I/F buffer 6.

In case the resistance value of the Nch output transistor, not shown, of the I/F buffer 6 is not coincident with the resistance value of the resistor 12 (NO branching of the step F5), processing reverts to the step F4 to perform re-adjustment.

In case the resistance value of the Nch output transistor, not shown, of the I/F buffer 6 is coincident with the resistance value of the resistor 12 (YES branching of the step F5), processing transfers to a step F6 to output the result of adjustment to the I/F buffer 6 to adjust the resistance value of the Nch output transistor, not shown.

In a step F7, the Pch pre-transistor, not shown, of the I/F buffer 6, is adjusted. The Pch pre-transistor resistance adjustment circuit 4 is activated to adjust the resistance value of the Pch pre-transistor, not shown, of the I/F buffer 6.

In case the resistance value of the Pch pre-transistor, not shown, of the I/F buffer 6 is not coincident with the resistance value of the resistor 13 (NO branching of the step F8), processing reverts to the step F7 to perform re-adjustment.

In case the resistance value of the Pch pre-transistor, not shown, of the I/F buffer 6 is coincident with the resistance value of the resistor 13 (YES branching of the step F8), processing transfers to a step F9 to output the result of adjustment to the I/F buffer 6 to adjust the resistance value of the Pch pre-transistor, not shown.

In a step F10, fine adjustment is made of the Pch pre-transistor, not shown, of the I/F buffer 6. The fine Pch pre-transistor resistance adjustment circuit 21 is activated to make fine adjustment of the waveform gradient by the reference capacitance 23.

In case of non-coincidence of the gradient (NO branching of the step F11), processing reverts to the step F10 to make re-adjustment.

In case of coincidence of the gradient (YES branching of the step F11), processing transfers to a step F12 to output the result of adjustment S25 to the I/F buffer 6 to adjust the resistance value of the Pch pre-transistor, not shown, of the I/F buffer 6. Based on the result of adjustment S25, adjustment is made of, for example, an adjustment pre-transistor buffer in the I/F buffer 6.

In a step F13, adjustment is made of the Nch pre-transistor, not shown, of the I/F buffer 6. The Nch pre-transistor resistance adjustment circuit 5 is activated to adjust the resistance value of the Nch pre-transistor of the I/F buffer 6.

In case the resistance value of the Nch pre-transistor, not shown, of the I/F buffer 6 is not coincident with the resistance value of the resistor 14 (NO branching of the step F14), processing reverts to the step F13 to perform re-adjustment.

In case the resistance value of the Nch output transistor, not shown, of the I/F buffer 6, is coincident with the resistance value of the resistor 14 (YES branching of the step F14), processing transfers to a step F15 to output the result of adjustment to the I/F buffer 6 to adjust the resistance value of the Nch pre-transistor, not shown.

In a step F16, fine adjustment is made of the Nch pre-transistor, not shown, of the I/F buffer 6. The fine Nch pre-transistor resistance adjustment circuit 22 is activated to make fine adjustment of the waveform gradient by the reference capacitance 24.

In case of non-coincidence of the gradient (NO branching of the step F17), processing reverts to the step F16 to make re-adjustment.

In case of coincidence of the gradient (YES branching of the step F17), processing transfers to a step F18 to output the result of adjustment to the I/F buffer 6 to adjust the resistance value of the Nch pre-transistor, not shown.

With the above steps, adjustment of the transistors of the I/F buffer 6 comes to a close. In a step F18, the operation of the I/F buffer 6 is initiated.

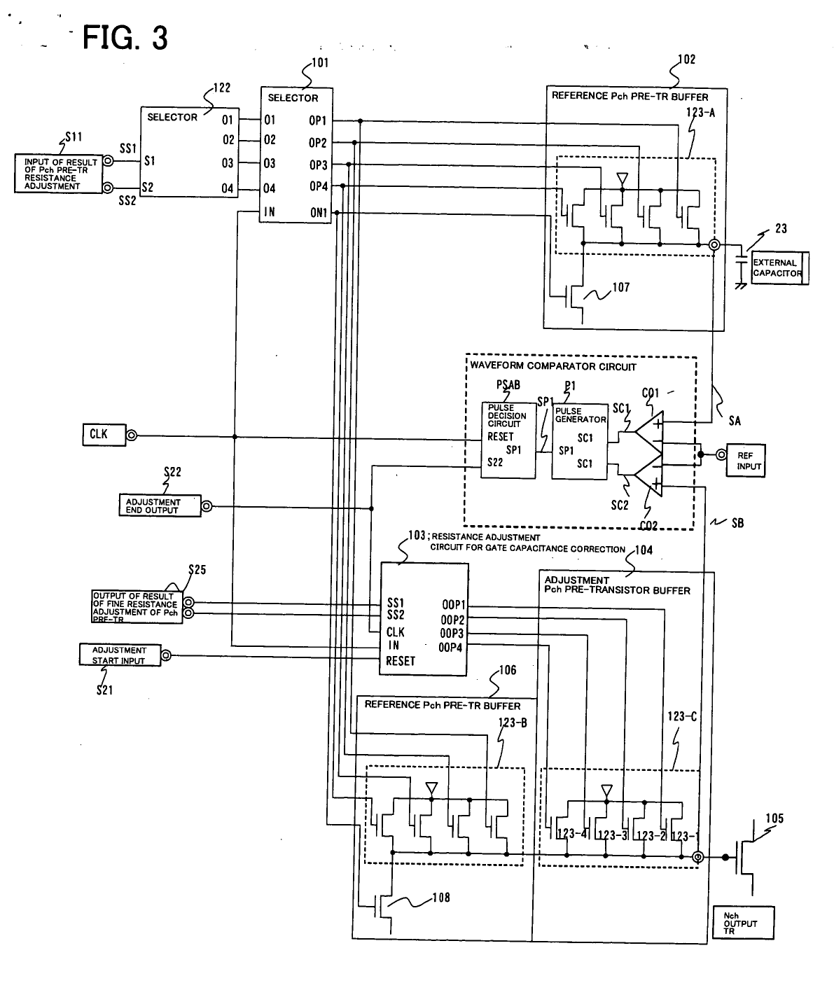

FIG. 3 shows the configuration of the fine Pch pre-transistor resistance adjustment circuit 21 according to the present invention.

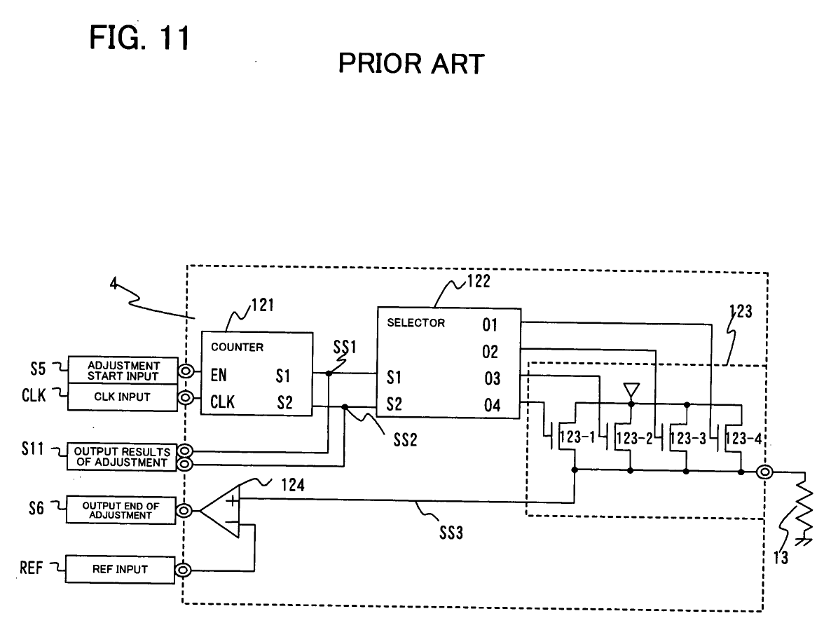

In FIG. 3, a selector 122 is the same circuit as the selector 122 of FIG. 11, and causes the states of the outputs O1 to O4 to be changed by the input signals S1 and S2.

On receipt of the outputs O1 to O4, as input signals, the selector 101 outputs the logic of IN from output terminals OP1, OP2, OP3 and OP4. An output terminal ON1 outputs the logic IN at all times. The states of the output terminals OP1, OP2, OP3, OP4 and ON1 are as shown in the following Table 2.

TABLE 2

| O1 | O2 | O3 | O4 | OP1 | OP2 | OP3 | OP4 | ON1 |
|---|---|---|---|---|---|---|---|---|
| L | H | H | H | IN | H | H | H | IN |
| L | L | H | H | IN | IN | H | H | IN |
| L | L | L | H | IN | IN | IN | H | IN |
| L | L | L | L | IN | IN | IN | IN | IN |

A set of Pch pre-transistors 123-A is of the same configuration as the set of Pch pre-transistors 123 of FIG. 11, and includes an Nch transistor 107 of sufficiently high driving power, connected to the drains of the transistors of the set of Pch pre-transistors 123-A. The set of Pch pre-transistors 123-A is constituted as a reference Pch pre-transistor buffer 102, and includes an external capacitor 23 connected to the drains of the transistors.

A resistance adjustment circuit for correcting the gate capacitance 103 is a selector synchronized with a clock signal CLK, and sequentially selects OOP1 to OOP4 to the same logic as that of IN, until RESET becomes LOW level, in synchronization with the rising of the clock signal CLK. The output terminals SS1 and SS2 output the states of selection of output terminals OOP1 to OOP3 with two bits.

The states of the output terminals OOP1, OOP2, OOP3, SS1 and SS2 are as shown in the following Table 3:

TABLE 3

| CLK | RESET | OOP1 | OOP2 | OOP3 | SS2 | SS1 |
|---|---|---|---|---|---|---|
| Rise once | H | H | H | H | L | L |
| Rise twice | H | IN | H | H | L | H |
| Rise thrice | H | IN | IN | H | H | L |
| Rise four | H | IN | IN | IN | H | H |
| times | | | | | | |

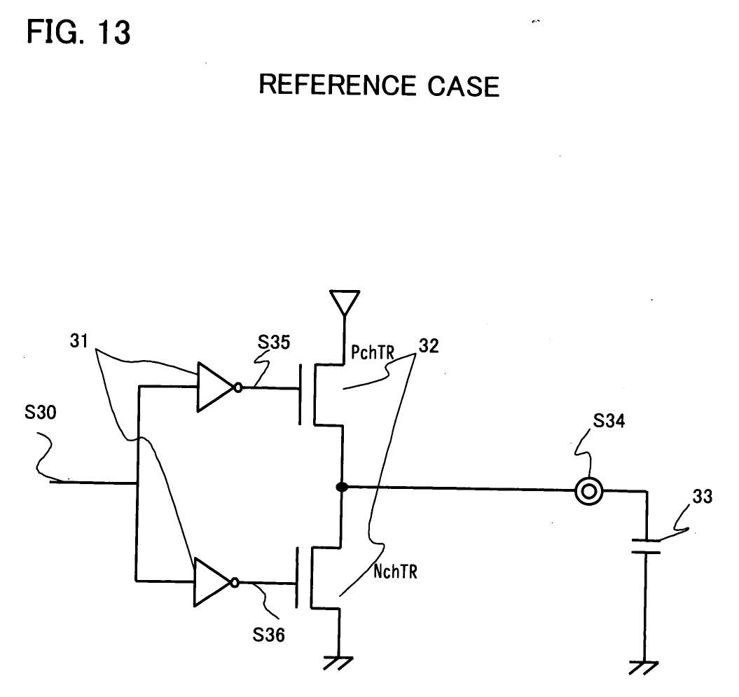

The outputs OP1 to OP4 of the selector 101 are connected to the gates of the four Pch transistors of the set of Pch pre-transistors 123-A of the reference Pch pre-transistor buffer 102. The drains of the four Pch transistors of the reference Pch pre-transistor buffer 102 are connected to the drain of the Nch transistor 107, the source of which is grounded. The Nch transistor 107 is of the same size as an Nch output transistor, not shown, of the I/F buffer 6 of FIG. 1. This Nch output transistor corresponds to the Nch TR of FIG. 13. The output terminals OP1 to OP4 of the selector 101 are connected to the gates of four Pch transistors of a set of Pch transistors 123B of the I/F buffer (reference Pch pre-transistor buffer 106). The drains of the Pch transistors of the set of Pch transistors 123B are connected to the drain of an Nch transistor 108, the source of which is grounded. The Nch transistor 108 is of the same size as the Nch output transistor of the I/F buffer 6 of FIG. 1 This Nch output transistor is not shown and corresponds to the Nch TR of FIG. 13.

A pair of comparators CO1 and CO2 are each a two-input voltage comparator. The comparator CO1 compares the reference voltage VREF with the voltage at the drain SA of the reference Pch pre-transistor buffer 102, and sets

SC1 to HIGH level if REF≧SA,

SC1 to LOW level if REF<SA.

The comparator CO2 compares the reference voltage VREF with the voltage at the drain SB of the adjustment Pch pre-transistor buffer 104, and sets

SC2 to HIGH level if REF≧SB,

SC2 to LOW level if REF<SB.

A pulse generator P1 is a circuit for outputting to an output SP1 a pulse of the rise time difference of outputs SC1 and SC2 of the comparators CO1 and CO2.

If the RESET input is LOW, and a pulse is supplied to the output SP1, a pulse decision circuit PSAB sets an output S22 to HIGH level by the rising of the pulse. If the RESET input is HIGH, the pulse generator sets the output S22 to LOW level.

The input for the result of Pch pre-TR resistance adjustment S11 is connected to the inputs S1 and S2 of the selector 122. The outputs OP1 to OP4 of the selector 122 are connected to the inputs O1 to O4 of the selector 101, while the outputs OP1 to OP4 of the selector 101 are connected to the gates of Pch transistors of the reference Pch pre-transistor buffers 102 and 106.

The output ON1 is connected to the gates of the Nch transistors 107, 108 of the reference Pch pre-transistor buffers 102 and 106. The common drain SA of the transistors of the set of Pch transistors 123-A of the reference Pch pre-transistor buffer 102 and the reference voltage REF are connected to the inputs of the comparator CO-1.

The common drain SB of the transistors of the set of Pch transistors 123-C of the adjustment Pch pre-transistor buffer 104 and the reference voltage REF are connected to the inputs of the comparator CO-2.

The outputs SC1, SC2 of the comparators CO1, CO2 are connected to input terminals SC1 and SC2 of the pulse generator P1, respectively. The output SP1 of the pulse generator P1 is connected to an input of the pulse decision circuit PSAB.

An output S22 of the pulse decision circuit PSAB is connected to the adjustment end output S22 and to a clock input terminal CLK of the resistance adjustment circuit for correcting the gate capacitance 103.

The outputs OOP1 to OOP4 of the resistance adjustment circuit for correcting the gate capacitance 103 are connected to the gates of the four Pch transistors 123-1 to 123-4 of the set of Pch transistors 123-C of the adjustment Pch pre-transistor buffer 104.

The clock input terminal CLK is connected to an input terminal IN of the selector 101, a reset terminal RESET of the pulse decision circuit PSAB, which is reset by a clock input, and to an input terminal IN of the resistance adjustment circuit for correcting the gate capacitance 103.

The outputs SS1 and SS2 of the resistance adjustment circuit for correcting the gate capacitance 103 are connected to an output for the result of fine Pch pre-transistor resistance adjustment S25. The reset terminal RESET of the resistance adjustment circuit for correcting the gate capacitance 103 is connected to an adjustment start input S21. The terminal RESET is reset by the adjustment start input S21.

The operation of the present embodiment, shown in FIG. 1, will now be described mainly with respect to the point of difference from FIG. 9.

When the adjustment end signal S6 of the Pch pre-transistor resistance adjustment circuit 4 is changed to HIGH level, and the adjustment has come to a close, the fine Pch pre-transistor resistance adjustment signal S21 of the adjustment controller circuit 1 is changed to HIGH level. Thus, the fine Pch pre-transistor resistance adjustment circuit 21 commences resistance adjustment to make the inner waveform by the reference capacitance 23 coincident with the inner waveform by an inner dummy output transistor. This causes the adjustment end signal S22 to be changed to HIGH level to advise the adjustment controller circuit 1 of the fact that the adjustment has come to a close. The adjustment of the Nch pre-transistor resistance adjustment circuit 5 is then commenced.

The signal for the result of fine Pch pre-transistor resistance adjustment S25 is output to the I/F buffer 6 to make the resistance value of the Pch pre-transistor of the I/F buffer 6 coincident with the resistance of the resistor 23 of the fine Pch pre-transistor resistance adjustment circuit 21.

When the adjustment end signal of the Nch pre-transistor resistance adjustment circuit 5 is changed to HIGH level, and the adjustment has come to a close, the fine Nch pre-transistor resistance adjustment signal S23 of the adjustment controller circuit 1 is changed to HIGH level. Thus, the fine Nch pre-transistor resistance adjustment circuit 22 commences resistance adjustment to make the inner waveform by the reference capacitance 24 coincident with the inner waveform by an inner dummy output transistor. This causes the adjustment end signal S24 to be changed to HIGH level to advise the adjustment controller circuit 1 of the fact that the adjustment has come to a close. In this manner, the adjustment operation comes to a close.

The fine Nch pre-transistor adjustment result signal S26 is output to the I/F buffer 6 to make the resistance value of the Nch pre-transistor of the I/F buffer 6 coincident with the resistor 24 of the fine Nch pre-transistor resistance adjustment circuit 22.

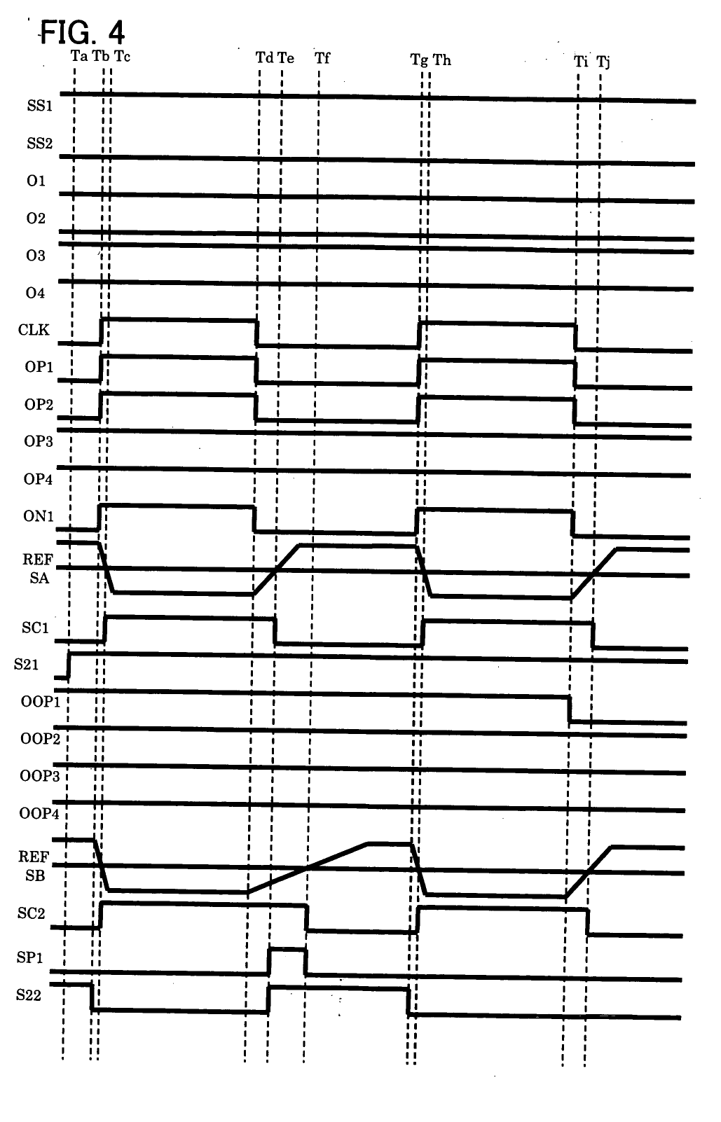

The operation of the circuit shown in FIG. 3 will now be described with reference to the timing chart of FIG. 4. For example, the outputs SS1 and SS2 are set to HIGH and LOW levels, respectively. The outputs O1 to O4 of the selector 122 are set so that O1=LOW level, O2=LOW level, O3=HIGH level and O4=HIGH level.

At time Ta, the adjustment start input S21 is changed from LOW level to HIGH level. This actuates the resistance adjustment circuit for correcting the gate capacitance 103.

At time Tb, the clock signal CLK rises. Thus, depending on the states of the outputs O1 to O4, the outputs OP1, OP2 and ON1 output the same logic as that of CLK, so that the voltage at the common drain node SA of the reference set of Pch transistors 123-A falls, while the voltage at the common drain node SB of the reference set of Pch transistors 123-C (adjustment pre-transistor buffer) also falls.

At time Tc, the voltages at the nodes SA and SB simultaneously fall to a level lower than the reference voltage VREF. Thus, the outputs SC1 and SC2 are simultaneously changed to the HIGH level.

At time Td, the clock signal CLK falls, and the outputs ON1, OP1 and OP2 rise.

In case the external capacitor 23 and the Nch output transistor 105 differ from each other in capacitance, the gradient of the rising waveform of the voltage at SA differs from that at SB, so that the time during which the waveform of the voltage at SA exceeds the reference voltage VREF differs from the time during which the waveform of the voltage at SB exceeds the reference voltage. Meanwhile, in the example shown in FIG. 4, the capacitance of the external capacitor 23 is set so as to be smaller than that of the Nch output transistor 105.

At time Te, the voltage at SA exceeds the reference voltage VREF, so that the output SC1 of the comparator CO1 falls. Then, at time Tf, SB exceeds the reference voltage VREF, so that the output SC2 of the comparator CO2 falls.

Due to the time difference between time Te and time Tf, there is generated a pulse at the output SP1. With the rising of the pulse, the adjustment result output S22 goes HIGH level.

At a time Tg, the clock signal CLK rises, while the output S22 goes to LOW level. At this time, selection by the resistance adjustment circuit for correcting the gate capacitance 103 is such that the output OOP1 will deliver the same output as that at the output IN. At time Th, the voltages at SA and SB become lower than the reference voltage VREF. The outputs SC1, SC2 of the comparators CO1, CO2 become HIGH from LOW level.

At time Ti, the clock signal CLK falls and the output OOP1 falls, while the outputs OP1, OP2 and ON1 also fall simultaneously.

The number of the Pch transistors which drives the gate of the Pch output transistor 105, is increased by the number of the Pch transistors of the adjustment Pch pre-transistor buffer 104. Thus, the rise time of SB as from time Ti becomes shorter than the rise time as from time Td, that is, the gradient becomes steeper, as shown in FIG. 4.

The waveforms at SA and SB coincide with each other and, at time Tj, SA and SB exceed the reference voltage REF, with the outputs SC1 and SC2 of the comparators CO1 and CO2 falling simultaneously. Hence, no pulse is generated at the output SP1, so that the output S22 is not changed in voltage, that is, the output is fixed at LOW level and adjustment comes to a close.

With the present embodiment, the resistance values of the Pch and Nch pre-transistors may be decreased or increased by 15%, even though the gate capacitances of the Pch and Nch output transistors are increased or decreased by 15%, such as to provide for constant gate potential transition of the Pch and Nch output transistors.

That is, adjustment is made so that, by adjusting the value of r (resistance) in the time constant rc in the gate potential transition exp(t/rc) of the output transistors in an amount corresponding to deviation of the capacitance c in the time constant, the time constant rc will become constant. By so doing, a constant slew rate and a constant influence by reflection on the transmission line may be assured to render it possible to generate a waveform which is not conductive to malfunctions of the input IC.

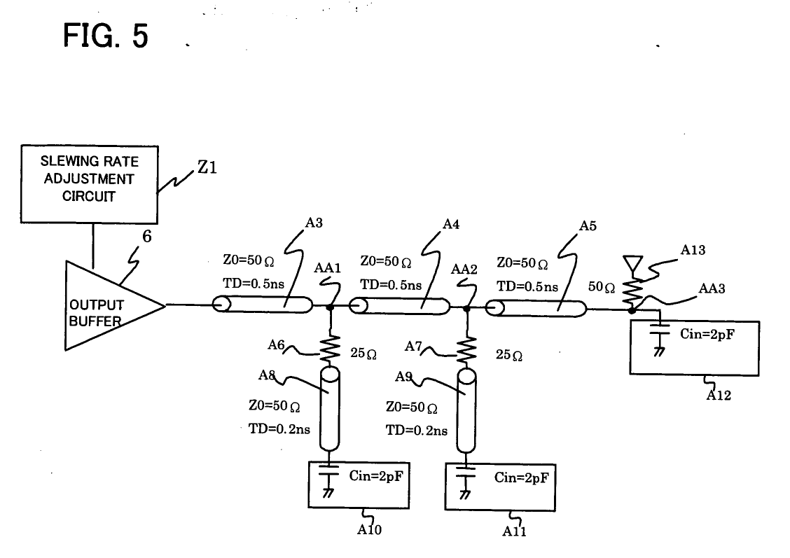

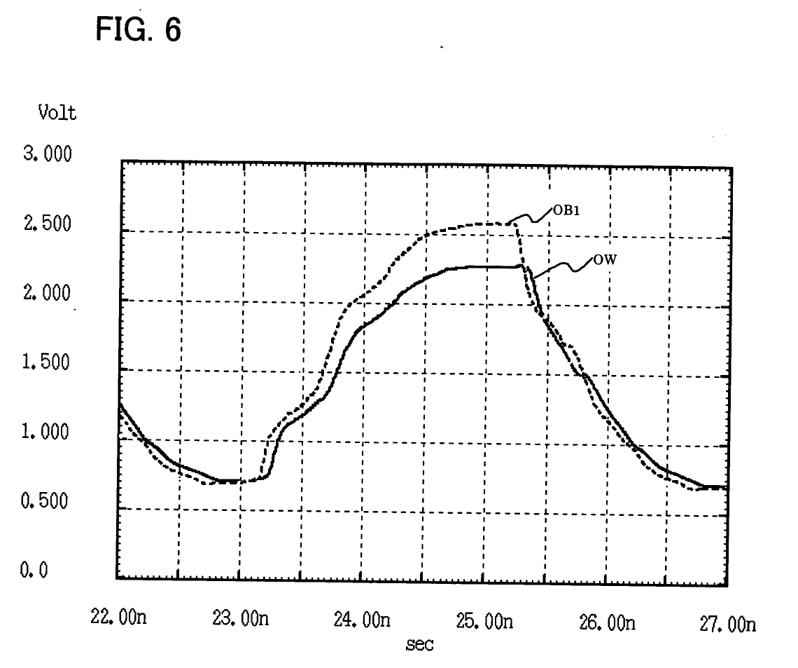

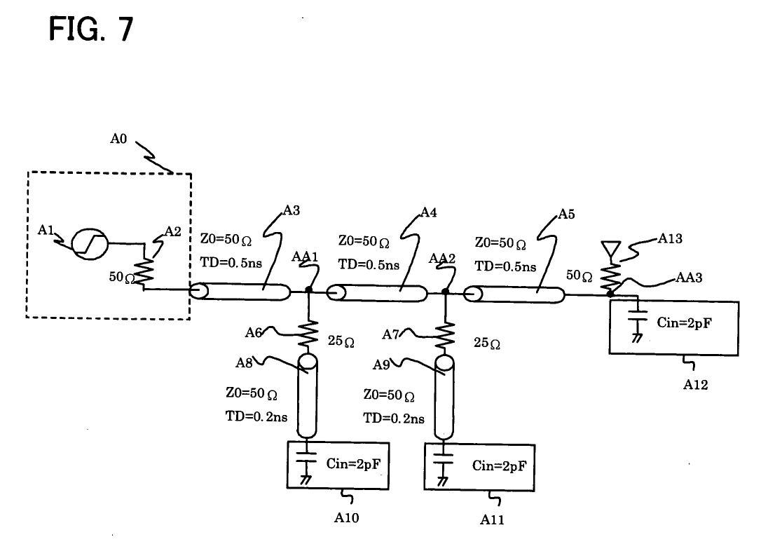

FIG. 5 shows an example of a transmission circuit of the instant embodiment. Specifically, FIG. 5 shows a circuit configuration in which the output buffer (I/F buffer) 6, adjusted by the slew rate adjustment circuit Z1 of the present invention, is substituted for the ideal output buffer A0 of FIG. 7. In FIG. 5, Z1 denotes a slew rate adjustment circuit explained with reference to FIG. 1, for example. FIG. 6 shows the waveform representing the results of simulation by SPICE of the circuit of FIG. 5.

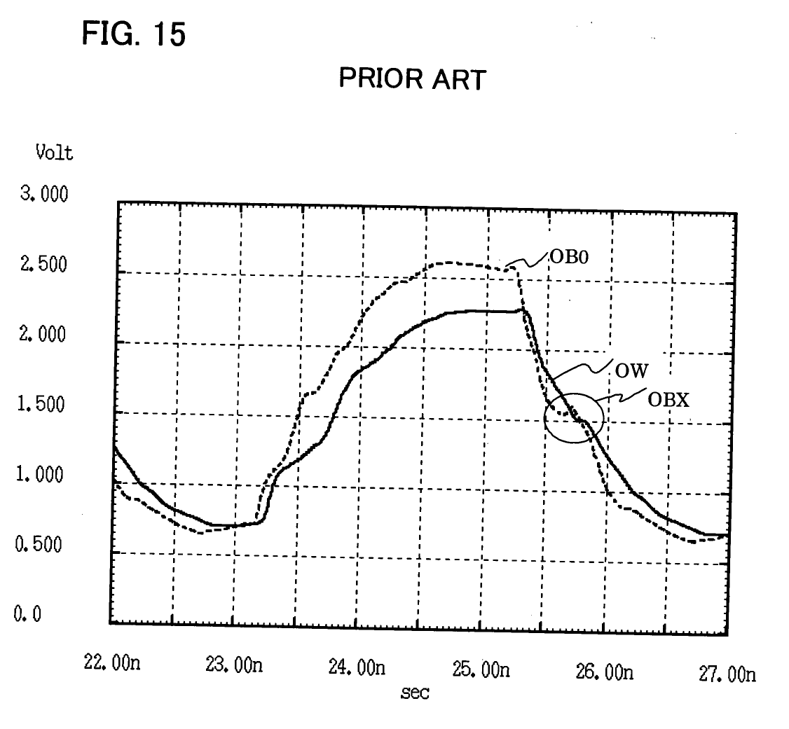

That is, OW in FIG. 6 shows a waveform at a node AA3 of FIG. 5 under the same conditions of fabrication and use as those for OW of FIG. 15, while OB1 shows a waveform at the node AA3 of FIG. 5 under the same conditions of fabrication and use as those for OB0 of FIG. 15.

That is, the waveform OB0 of FIG. 15 suffers from a step difference responsible for possible IC malfunctions at OBX, while the waveform OB1 of FIG. 6 is free from such step difference. The meritorious effect in the SPICE simulation has also been confirmed.

In the present embodiment, it is of course possible to prohibit the malfunction of the circuit receiving an output signal of the output buffer 6 (input IC) by maintaining a constant slew rate in the output buffer 6. In addition, it is possible to increase the margin in the timing designing.

Although the present invention has so far been explained with reference to the preferred embodiments, the present invention is not limited to the particular configurations of these embodiments. It will be appreciated that the present invention may encompass various changes or corrections such as may readily be arrived at by those skilled in the art within the scope and the principle of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A slew rate adjustment circuit for adjusting a slew rate of an output buffer which includes an output transistor and a pre-buffer arranged in a preceding stage of said output transistor, said slew rate adjustment circuit comprising
a control circuit that variably controls the resistance value of a transistor of said pre-buffer depending on the gate capacitance of said output transistor; wherein the resistance value of said transistor of said pre-buffer is adjusted so as to cancel out variations in a gate capacitance of said output transistor to cause the slew rate of said output transistor to be adjusted to a preset value.

2. The slew rate adjustment circuit according to claim 1, comprising:
a first resistance adjustment circuit that adjusts the resistance of an output transistor of a first conductivity type of said output buffer;
a second resistance adjustment circuit that adjusts the resistance of an output transistor of a second conductivity type of said output buffer;
a third resistance adjustment circuit that adjusts the resistance of a pre-transistor of the first conductivity type of said pre-buffer;
a fourth resistance adjustment circuit that adjusts the resistance of a pre-transistor of the second conductivity type of said pre-buffer;
a first fine resistance adjustment circuit that receives the result of adjustment by said third resistance adjustment circuit, performs fine adjustment of the resistance value of said pre-transistor of the first conductivity type of said pre-buffer, and performs fine adjustment of the waveform gradient based on a reference capacitance; and
a second fine resistance adjustment circuit that receives the result of adjustment by said fourth resistance adjustment circuit, performs fine adjustment of the resistance value of said pre-transistor of the second conductivity type of said pre-buffer, and performs fine adjustment of the gradient of said waveform based on another reference capacitance; wherein
the results of adjustment by said first resistance adjustment circuit and said second resistance adjustment and the results of adjustment by said first fine resistance adjustment circuit and said second fine resistance adjustment circuit are supplied to said output buffer as inputs to control the slew rate of said output buffer.

3. The slew rate adjustment circuit according to claim 2, wherein said first fine resistance adjustment circuit includes:
a first transistor of a second conductivity type that has a gate of supplied with a clock signal;
a first reference pre-transistor buffer that includes a plurality of transistors of the first conductivity type, said plurality of transistors being connected in parallel one with another between said first transistor of the second conductivity type and a power supply and being on/off controlled by control signals applied to the respective gates of said plurality of transistors;
a second transistor of the second conductivity type that has a gate supplied with said clock signal;
a second reference pre-transistor buffer including a plurality of transistors of the first conductivity type, said plurality of transistors being connected in parallel one with another between said second transistor of the second conductivity type and the power supply and being on/off controlled by control signals applied to the respective gates of said plurality of transistors;
an adjustment pre-transistor buffer including a plurality of transistors of the first conductivity type, said plurality of transistors being connected in parallel one with another between said second transistor and the power supply and being on/off controlled by control signals applied to the respective gates of the transistors;
an external capacitor that has one end supplied with an output of said first reference pre-transistor buffer and constituting said reference capacitance;
an output transistor that has a gate supplied with an output of said adjustment pre-transistor buffer;
a waveform comparator circuit that compares the waveform of an output signal of said first reference pre-transistor buffer and the waveform of an output signal of said adjustment pre-transistor buffer to each other and outputs an adjustment end signal based on the result of comparison; and
a gate capacitance correction circuit that receives said adjustment end signal output from said waveform comparator circuit and outputs a control signal to be supplied to the gate of said adjustment pre-transistor buffer.

4. The slew rate adjustment circuit according to claim 2, wherein said second fine resistance adjustment circuit includes
a first transistor of a first conductivity type that has a gate supplied with a clock signal;
a first reference pre-transistor buffer including a plurality of transistors of the second conductivity type, said plurality of transistors being connected in parallel one with another between said first transistor of the first conductivity type and a power supply and being on/off controlled by control signals applied to the respective gates of said plurality of transistors;
a second transistor of the first conductivity type that has a gate supplied with said clock signal;
a second reference pre-transistor buffer including a plurality of transistors of the second conductivity type, said plurality of transistors being connected in parallel one with another between said second transistor of the first conductivity type and the power supply and being on/off controlled by control signals applied to the respective gates of said plurality of transistors;
an adjustment pre-transistor buffer including a plurality of transistors of the second conductivity type, said plurality of transistors being connected in parallel one with another between said second transistor and the power supply and being on/off controlled by control signals applied to the respective gates of the transistors;
an external capacitor that has an end supplied with an output of said first reference pre-transistor buffer and constitutes said reference capacitance;
an output transistor that has a gate supplied with an output signal of said adjustment pre-transistor buffer;
a waveform comparator circuit that compares the waveforms of an output signal of said first reference pre-transistor buffer and an output signal of said adjustment pre-transistor buffer to each other and outputting an adjustment end signal based on the result of comparison; and
a gate capacitance correction circuit that receives said adjustment end signal output from said waveform comparator circuit as an input and outputs a control signal to be supplied to the gate of said adjustment pre-transistor buffer.

5. The slew rate adjustment circuit according to claim 3, wherein said first fine resistance adjustment circuit includes a circuit that receives the result of adjustment by said third resistance adjustment circuit and generates a signal to be supplied to the gates of a plurality of transistors of the second conductivity type of said first and second reference pre-transistor buffers in association with an output of the result of adjustment by said third resistance adjustment circuit.

6. The slew rate adjustment circuit according to claim 4, wherein said second fine resistance adjustment circuit includes a circuit that receives the result of adjustment by said fourth resistance adjustment circuit as an input to generate a signal to be supplied to the gates of a plurality of transistors of the second conductivity type of said first and second reference pre-transistor buffers in association with an output of the result of adjustment by said third resistance adjustment circuit.

7. The slew rate adjustment circuit according to claim 2, wherein said first and third resistance adjustment circuits each include:
a counter for counting an input clock signal;
a plurality of transistors of the first conductivity type that have gates supplied with output of said counter and are connected in parallel one with another between a power supply and a reference resistor; and
a comparator that compares the voltage at a connection node of said plural transistors of said first conductivity type and said reference resistor and an input reference voltage to output an adjustment end signal based on the result of comparison;
an output of said counter at the end of adjustment being used as said result of adjustment.

8. The slew rate adjustment circuit according to claim 2, wherein said second and fourth resistance adjustment circuits each include
a counter that counts an input clock signal;
a plurality of transistors of the second conductivity type, that have gates supplied with an output of said counter and are connected in parallel one with another between a power supply and a reference resistor; and
a comparator that compares the voltage at a connection node of said plural transistors of said second conductivity type and said reference resistor and an input reference voltage to output an adjustment end signal based on the result of comparison;
an output of said counter at the end of adjustment being used as said result of adjustment.

9. The slew rate adjustment circuit according to claim 2, wherein
resistance adjustment by said first and second resistance adjustment circuits is carried out sequentially and the results of adjustment are supplied to said output buffer;
resistance adjustment by said third and that by said fourth resistance adjustment circuits is carried out sequentially; adjustment of the waveform gradient by the reference capacitance in said first fine resistance adjustment circuit and that in said second fine resistance adjustment circuit are carried out sequentially; and wherein
the results of adjustment by said first and second fine resistance adjustment circuits are supplied to said output buffer.
